(19) United States
(12) Patent Application Publication
(10) Pub. No.: US 2015/0213881 A1
(43) Pub. Date: Jul. 30, 2015

(54) INTEGRATED READ/WRITE TRACKING IN SRAM

(71) Applicant: LSI Corporation, San Jose, CA (US)

(72) Inventors: Dharmendra Kumar Rai, Bangalore (IN); Rahul Sahu, Bangalore (IN)

(73) Assignee: LSI CORPORATION, San Jose, CA (US)

(21) Appl. No.: 14/179,681

(22) Filed: Feb. 13, 2014

Related U.S. Application Data
(60) Provisional application No. 61/933,129, filed on Jan. 29, 2014.

(51) Int. Cl. G11C 11/419

(52) U.S. Cl. CPC G11C 11/419

(57) ABSTRACT

Systems and methods presented herein provide for integrated read/write tracking in an SRAM device. In one embodiment, an SRAM device includes a clock, a memory cell array, a column of dummy bit cells operable to mirror bit line loading of the memory cell array, and a row of dummy bit cells operable to mirror word line loading of the memory cell array. The SRAM devices also includes a read/write tracking cell operable to track read operations from the memory cell array via the dummy bit cells, to track write operations to the memory cell array via the dummy bit cells, and to reset the clock based on the tracked read operations and the tracked write operations.

### CROSS REFERENCE TO RELATED APPLICATIONS

This document claims priority to, and thus the benefit of an earlier filing date from, U.S. Provisional Patent Application No. 61/933,129 (filed on Jan. 29, 2014) entitled “INTEGRATED READ/WRITE TRACKING IN SRAM”, which is hereby incorporated by reference.

### FIELD OF THE INVENTION

The invention generally relates to field of SRAM devices.

### BACKGROUND

In Static Random Access Memory (SRAM) devices, read and write operations are tracked to allow the devices to be “self-timed”. Self-timing means automatically shutting off/resetting various internal operations of the devices, such as word line operations, internal clock generation, etc., to establish appropriate signal timing for write operations. Often, read/write tracking uses a column of dummy bit cells to provide bit line tracking for read operations and a separate column of dummy bit cells to provide bit line tracking for write operations. For example, when a memory cell in a memory cell array of an SRAM device is read, there is a corresponding read from a dummy bit cell in a read column of dummy bit cells to track the read operation of the memory cell array. And, when there is a write to a memory cell in the memory cell array, there is a corresponding write to a dummy bit cell in a separate write column of dummy bit cells to track the write operation of the memory cell array. SRAM devices incur an area penalty with two or more columns of dummy bit cells and their associated circuitries.

### SUMMARY

Systems and methods presented herein provide for integrated read/write tracking in an SRAM device. In one embodiment, an SRAM device includes a clock, a memory cell array, a column of dummy bit cells operable to mirror bit line loading of the memory cell array, and a row of dummy bit cells operable to mirror word line loading of the memory cell array. The SRAM device also includes a read/write tracking cell operable to track read operations from the memory cell array via the dummy bit cells, to track write operations to the memory cell array via the dummy bit cells, and to reset the clock based on the tracked read operations and the tracked write operations.

The various embodiments disclosed herein may be implemented in a variety of ways as a matter of design choice. For example, the embodiments may take the form of computer hardware, software, firmware, or combinations thereof. Other exemplary embodiments are described below.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a block diagram of an exemplary SRAM device.

FIG. 2 is a flowchart of an exemplary process operable with the SRAM device of FIG. 1.

FIG. 3 is a more detailed embodiment of the exemplary SRAM device of FIG. 1.

FIG. 4 is an exemplary circuit diagram of a read/write tracking cell of the SRAM device of FIG. 1.

FIGS. 5A and 5B is are exemplary circuit diagrams of read reset logic of the SRAM device of FIG. 1.

FIGS. 6A-6C are exemplary circuit diagrams of write reset logic of the SRAM device of FIG. 1.

FIG. 7 is a waveform diagram obtained during an exemplary read tracking operation.

FIG. 8 is a waveform diagram obtained during an exemplary write tracking operation.

FIG. 9 is a block diagram of an exemplary computing system in which a computer readable medium provides instructions for performing methods herein.

### DETAILED DESCRIPTION OF THE FIGURES

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention and are to be construed as being without limitation to such specifically recited examples and conditions. As a result, the invention is not limited to the specific embodiments or examples described below.

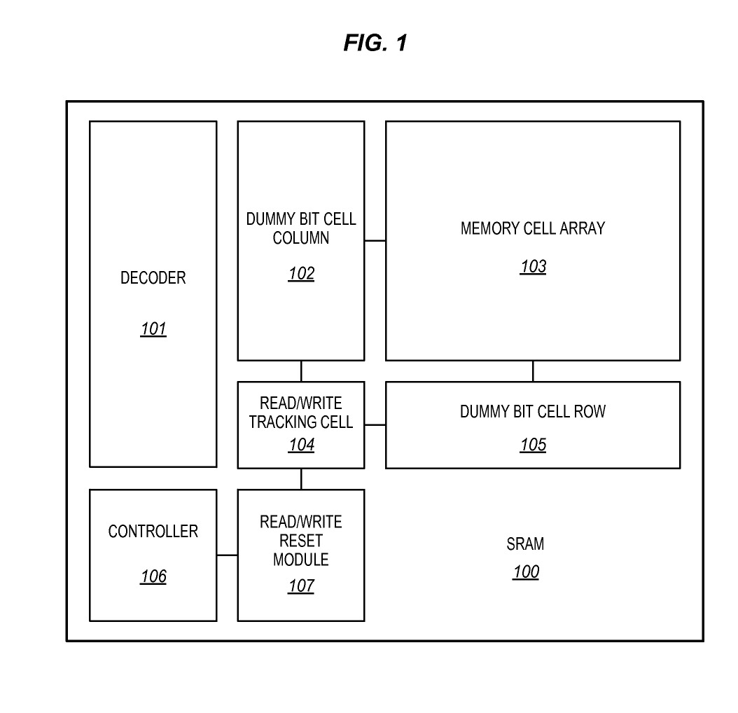

FIG. 1 is a block diagram of an exemplary SRAM device 100. The SRAM device includes, among other things, a controller 106, a decoder 101, and a memory cell array 103. The memory cell array 103 is operable to store bits of information and is configured generally as an N×M array of bit cells or memory cells (used interchangeably herein) constructed from Metal Oxide Semiconductor Field Effect Transistors, or “MOSFETs” (where “N” and “M” is simply intended to represent integers greater than 1 and not necessarily to any other N or M representation designated herein). In one embodiment, the SRAM device is a single-port SRAM device.

The controller 106 provides, among other things, a clock which times the reading and writing operations to the bit cells in the memory cell array 103. The decoder 101 is controlled also by the clock of the controller 106 and provides addressing for the reading and writing operations to the bit cells via word lines and bit lines in a column and row format. For example, word lines row-wise address the memory cell array 103 whereas bit lines column-wise address the memory cell array 103.

To implement self-timing in the SRAM device 100, the SRAM device 100 includes a column of dummy bit cells 102 and a row of dummy bit cells 105. The column of dummy bit cells 102 is operable to mirror both read and write bit line loading of the memory cell array 103. The row of dummy bit cells 105 is operable to mirror both read and write word line loading of the memory cell array 103. The dummy bit cells 102 and 105 are generally constructed in the same fashion as the memory cells of the memory cell array 103 so as to simplify fabrication. However, the dummy bit cells 102 and 105 may be configured in other ways as a matter of design choice.

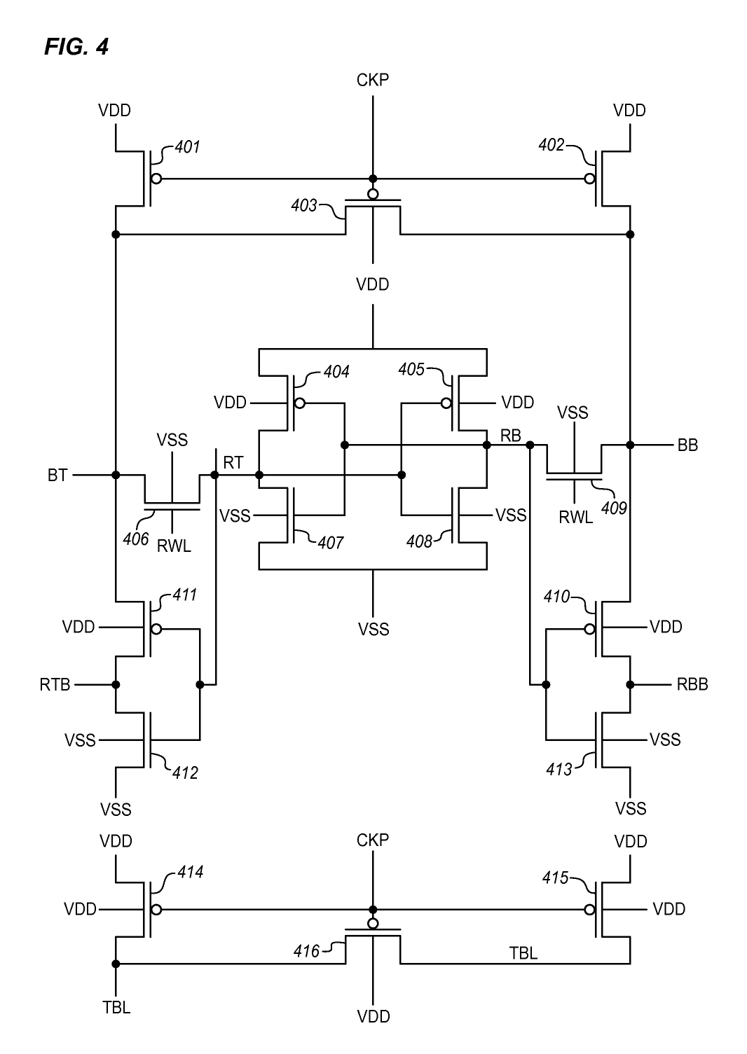

The SRAM device 100 also includes a read/write tracking cell 104 operable to track read and write operations to the memory cell array 103. More particularly, the read/write tracking cell 104 is operable to track any combination of read and write operations to the memory cell array 103 without having to restore the read/write tracking cell 104. In other words, the read/write tracking cell 104 can perform a read operation, reset the clock of the controller 106, and then perform a write operation or another read operation without first having to change a bit state of the read/write tracking cell 104. The dummy row of bit cells 105 is used for word line load modeling of the memory cell array 103 whereas the dummy column of bit cells is used for bit line load modeling of the memory cell array 103. Read and write operations are individual tracked/mirrored in the read/write tracking cell 104. For example, the read/write tracking cell 104 is constructed with a memory cell, similar to the dummy bit cells 102 and 105 and the memory cells of the memory cell array 103. Once a read operation or a write operation takes place, then the bit of the memory cell in the read/write tracking cell 104 simply remains until the next read or write operation. Exemplary details of the read/write tracking cell 104 are shown and described below in FIG. 4.

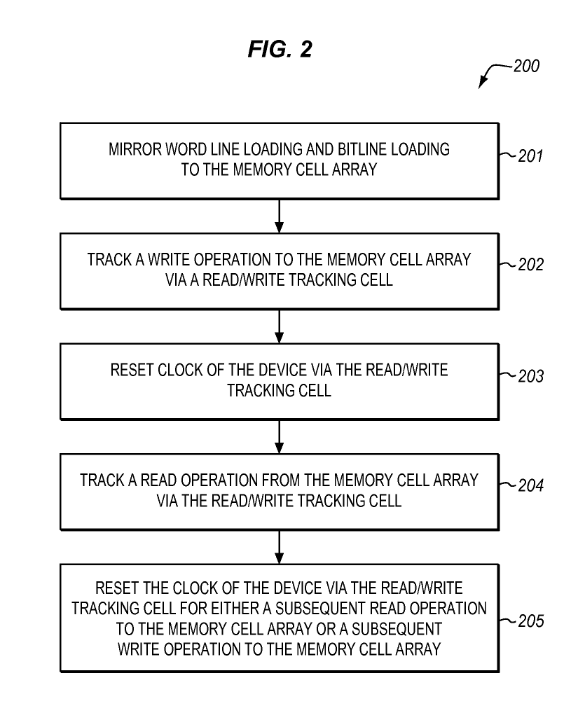

FIG. 2 is a flowchart of an exemplary process 200 operable with the SRAM device 100. In this embodiment, the read/write tracking cell 104 mirrors write line loading and bit line loading to the memory cell array 103 (e.g., via a dummy bit cell), in the process element 201. The read/write tracking cell 104 tracks the write operation of the memory cell array 103, in the process element 202, generally by duplicating the bit written to the memory cell array 103 (e.g., via a dummy bit cell). That is, the read/write tracking cell 104 stores the same bit in a memory cell within the read/write tracking cell 104.

Once the write operation is tracked, the read/write tracking cell 104 resets the internal clock of the SRAM device 100, in the process element 203, such that another operation may be tracked, in the process element 204. As illustrated in this flowchart, a read operation is next tracked from the memory cell array 103 with (e.g., via another dummy bit cell) after the clock is reset, in the process element 204. But, this is just for illustrative purposes as the read/write tracking cell 104 is operable to reset the clock of the SRAM device 100 and track any subsequent read or write operation to the memory cell array 103, as illustrated in the process element 205. After tracking the subsequent read/write operation, the read/write tracking cell 104 again resets the clock of the SRAM device 100 to prepare for another read or write operation.

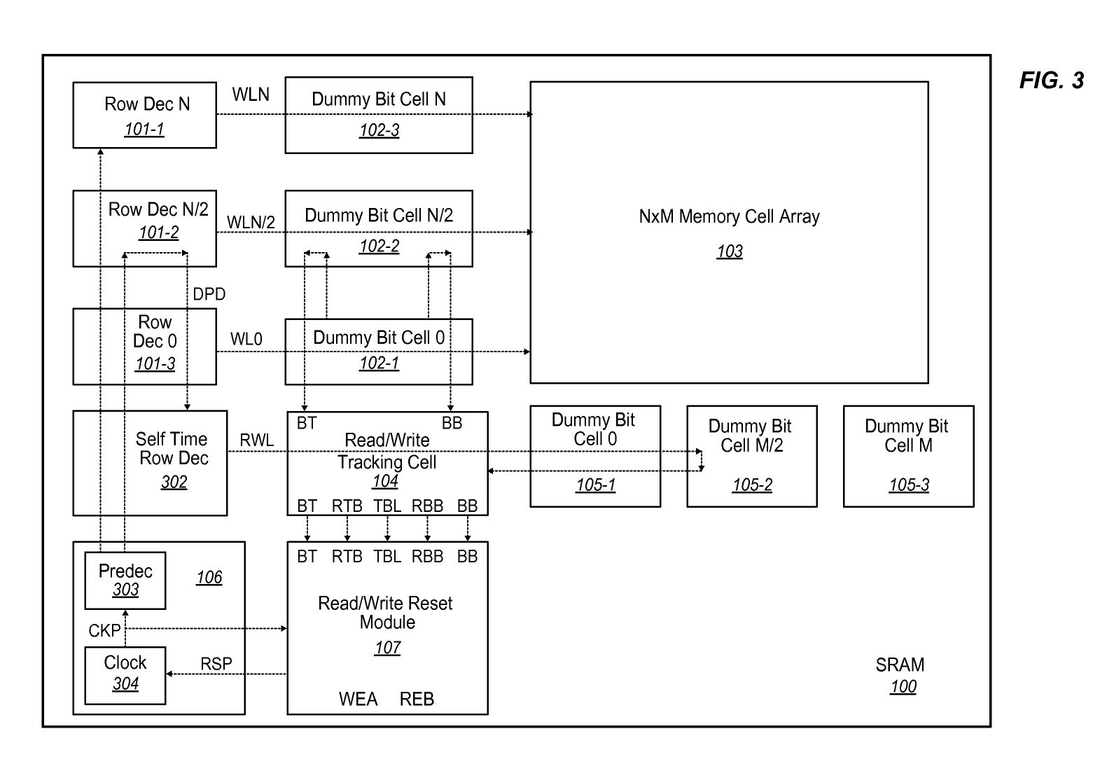

FIG. 3 is a more detailed embodiment of the exemplary SRAM device 100. In this embodiment, there is a column of dummy bit cells 102 with an even number “N” of dummy bit cells 102 with the N^{th} dummy bit cell being dummy bit cell 102-3, corresponding to the N^{th} number of word line memory cells in the memory cell array 103. A row of dummy bit cells 105 is configured with the SRAM device 100 with an even number “M” of dummy bit cells 105 with the M^{th} dummy bit cell being dummy bit cell 105-3 corresponding to the M^{th} number of bits line memory cells in the memory cell array 103.

A column of row decoders 101 provides addressing for operations on the word lines WL0-WLN coupled to the dummy bit cells 102-1-102-3 and the memory cells of the memory cell array 103. A row of column decoders performs similar bit line operations for the dummy bit cells 105-1-105-3, although they are not shown in this embodiment so as to simplify the figure for the reader. Column decoders and row decoders are known to those skilled in the art. A predecoder 303 is configured with the controller 106 to provide the SRAM device 100 with predecoding. Predecoding causes common gates of MOSFETs in memory cells of the memory cell array 103 to be factored out and thus reduces area.

The SRAM device 100 also comprises a self-time row decoder 302 that provides a dummy predecoder line DPD and a reference word line RWL. The DPD is modeled with same resistance/capacitance (RC) as predecoder lines from the predecoder 303. The DPD traverses halfway vertically through the row decoders 101 (i.e., to the row decoder 101-2) and returns to self-time row decoder 302. The self-time row decoder 302 provides a reference word line RWL to the read/write tracking cell 104. The RWL is modeled with an RC load as the normal word-lines WL0 to WLN. The reference word line RWL traverses half way horizontally through the dummy did cells 105 (i.e., to the dummy bit cell 105-2) and returns to the read/write tracking cell 104. Bit-lines BB and BT (complement) are tracking bit-lines which mimic the RC load of normal bit-lines to the memory cell array 103. Either of the BB or BT discharges during a read cycle as per the state of read/write tracking cell 104, which is subsequently transferred to a read tracking bit line via a tracking bit line signal TBL.

As mentioned, the controller 106 generates a clock signal. The internal clock 304 is operable to receive a clock signal from an external clock and generate the internal clock signal CKP. The clock signal CKP is conveyed to the predecoder 303 and a read/write reset module 107. The read/write reset module 107 provides the read/write reset logic (via the reset signal RSP) to reset the internal clock 304 between read and write operations.

Additional details regarding the read/write tracking cell 104 and the read/write reset module 107 are now described with reference to FIGS. 4, 5A and 5B, and 6A-6C. FIG. 4 is an exemplary circuit diagram of the read/write tracking cell 104 of the SRAM device 100. The read/write tracking cell 104 comprises a memory cell configured from N-channel MOSFETS 406, 407, 408, and 409 and P-channel MOSFETS 404 and 405. The memory cell of the read/write tracking cell 104 is coupled to the tracking bit lines BB and BT via the MOSFETs 406 and 409.

The read/write tracking cell 104 is coupled to the read tracking bit line TBL via a precharge device configured from the P-channel MOSFETs 414, 415, and 416. The precharge device provides precharge logic for the tracking bit line signal TBL. Another pre-charging device configured from the P-channel MOSFETs 401 402 and 403 provides precharge logic for the bit lines BT and BB.

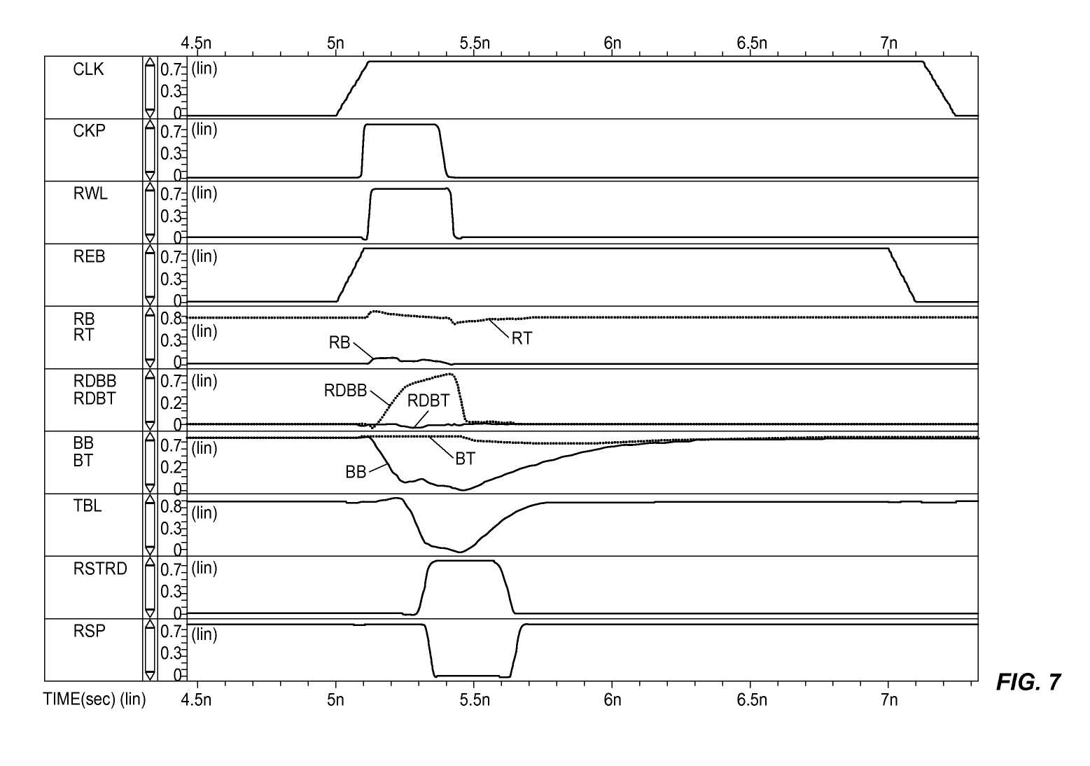

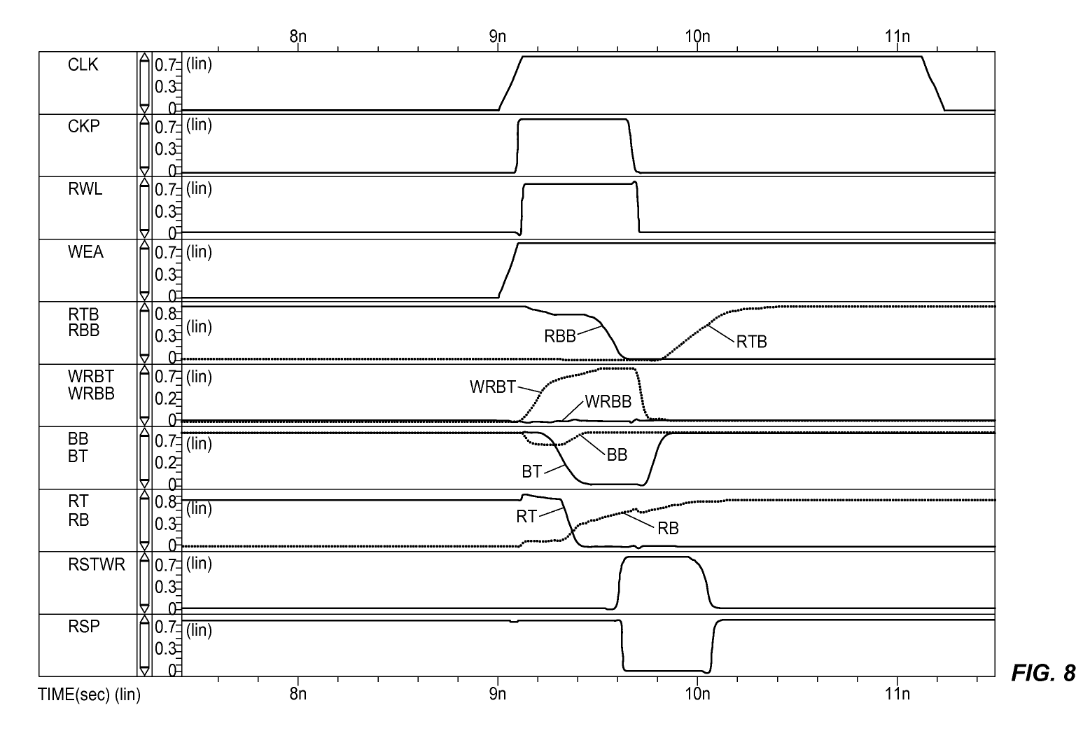

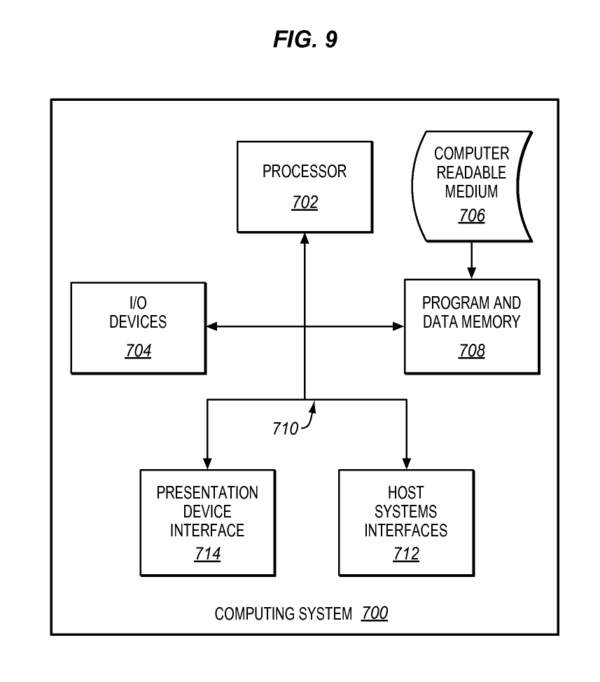

The reference word line RWL is applied to the MOSFETs 406 and 409 and is a derivative of the internal clock signal CKP, again modeled with the same RC load as the normal word lines WL0-WLN. The read/write tracking cell 104 has an internal node RTB configured with a node sensor from P-channel MOSFET 411 and N-channel MOSFET 412 operable to detect a signal from the read/write reset module 107 (hereinafter, the RTB signal). The read/write tracking cell 104 as another internal node RTB configured with a node sensor from the P-channel MOSFET 410 and N-channel MOSFET 413 operable to detect a signal from the read/write reset module 107 (hereinafter the RBB signal). The signaling of the read/write tracking cell 104, such as the RTB and RBB signals, and others are shown and described in greater detail below in FIGS. 7 and 8. It should also be noted that the references of VDD and VSS illustrated herein are the voltage supply for the devices (a.k.a. voltage “rails”).

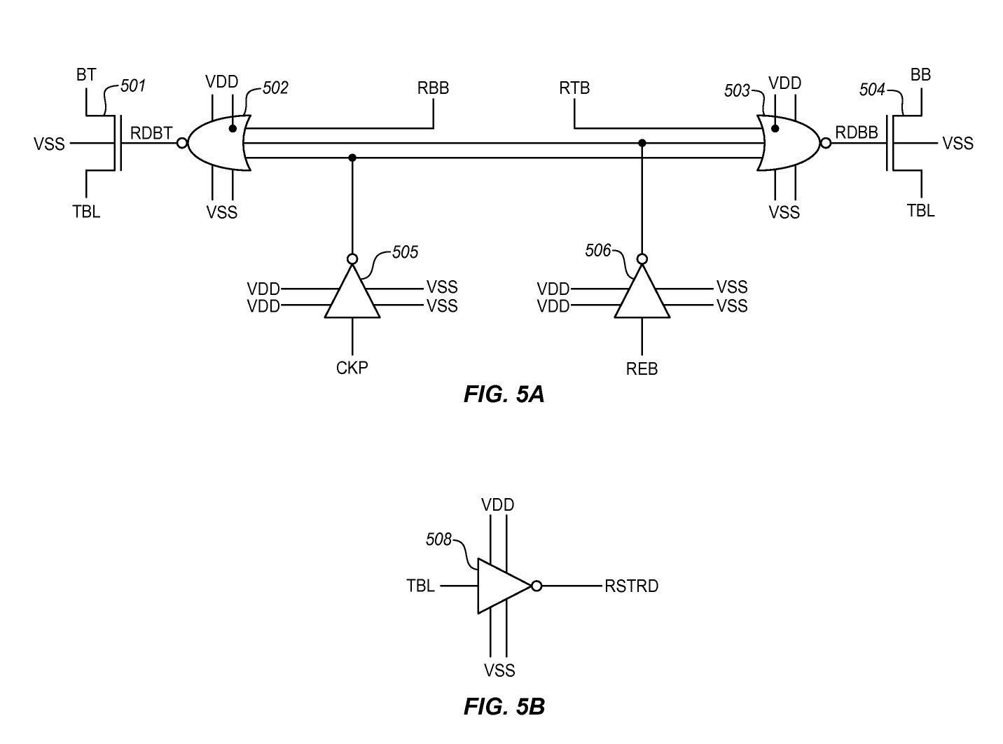

FIGS. 5A and 5B are exemplary circuit diagrams illustrating read enable and reset signaling of the read/write reset module 107. This portion of the read/write reset module 107 resets the read/write tracking cell 104 after a read operation or a write operation and prepares the read/write tracking cell 104 for a tracked read operation thereafter (i.e., without having to change the state of the memory cell configured from the MOSFETs 404, 405, 407, and 408 in FIG. 4). REB, coupled to the inverter 506, is a read enable signal that goes to logical “high” during a read cycle to enable read tracking during the read cycle. The tracking bit line BT is coupled to the source of the N-channel MOSFET 501 and the complement tracking bit line BB is coupled to the source of the N-channel MOSFET 504 to provide the tracking bit line signal TBL. The read tracking bit line signal RDBT is generated by the NOR device 502 when the internal clock signal CKP and the read enable signal REB go to logical high and when the RBB signal goes to logical “low”. Its complement, the read tracking bit line signal RDBB, is generated by the NOR device 503 and goes to logical low when the internal clock signal CKP and the read enable signal REB go to logical high and when the RBB signal goes to logical low. The read reset signal RSTRD is generated by the inverter 508 and goes logical high when the tracking bit line signal TBL goes to logical low.

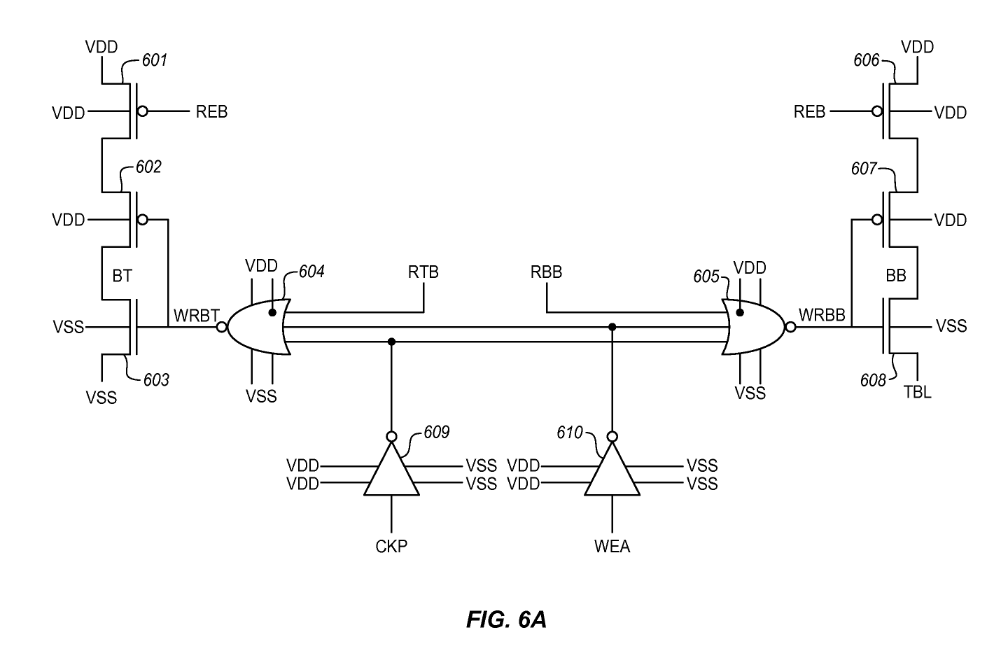

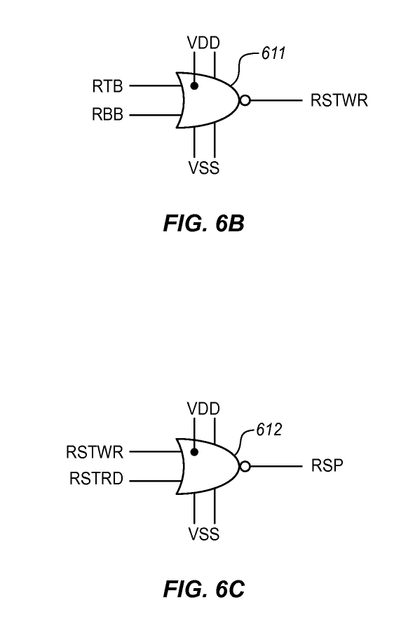

FIGS. 6A-6C are exemplary circuit diagrams illustrating the write enable and reset signaling of the read/write reset module 107. This portion of the read/write reset module 107 resets the read/write tracking cell 104 after a read operation or a write operation and prepares the read/write tracking cell 104 for a tracked write operation thereafter (again, without changing the bit of the memory cell of MOSFETs 404, 405, 407, and 408 in FIG. 4). The write enable signal WEA goes to logical high during a write cycle to trigger tracking of the write operation. The tracking bit line BT is coupled to the source of the N-channel MOSFET 603 and the complement tracking bit line BB is coupled to the source of the N-channel MOSFET 608.

The write tracking bit line signal WRBT is generated by the NOR device 604 when the internal clock signal CKP and the write enable signal WEA go to logical high and when the RTB signal goes logical low. Its complement, WRBB, is generated by the NOR device 605 when the internal clock signal CKP and the write enable signal go to logical high and the RBB signal is logical low. The write reset signal is generated by the NOR device 611 and goes logical high when both the RTB and RBB signals are logical low. The tracking write drivers of the read/write reset module 107 are provided by the MOSFETS 601 602, 603, 606, 607, and 608 in FIG. 6A. These tracking write drivers provide for one of the tracking bit lines BT or BB to go logical low in order to perform a dummy write operation in the memory cell of the read/write tracking cell 104 (i.e., in the MOSFETs 404, 405, 407, and 408 of FIG. 4).

The overall reset signal RSP resets the read/write tracking cell 104 for a subsequent read operation or a subsequent write operation. The reset signal RSP is generated by the NOR device one 612 when any of the reset signals (i.e., RSTWR for write tracking or RSTRD for read tracking) go to logical high, thereby completing the tracking of the read or write operation.

FIG. 7 illustrates a signaling diagram during an exemplary read tracking operation. An external clock CLK is provided to the internal clock 106 to generate the internal clock signal CKP. During the read cycle, the read enable signal REB is logical high. When the internal clock signal CKP arrives at the read/write reset module 107 and depending on the state of the RTB and RBB signals, the RDBT signal or the RDBB signal is triggered to logical high. Thus, the RTB signal and the RBB signal is logical high triggering the RDBB signal to logical high. The internal clock signal CKP and the dummy predecoder line DPD generate the reference word line RWL, which in turn travels horizontally halfway through the dummy bit cells to the dummy bit cell 105-2 of the SRAM device 100 to imitate the normal word line. The reference word line RWL thereby turns on the read/write tracking cell 104 and starts a discharge of any of the tracking bit lines BT or BB on the basis of the data stored in the memory cell of the read/write tracking cell 104.

If the RTB node is pulled logical high and the RBB node is pulled logical low, the bit line BB discharges with the arrival of the reference word line signal RWL. Since the read tracking bit line signal RDBB is logical high, the state of the bit line BB is transferred to the tracking bit line signal TBL. With the tracking bit line signal TBL going logical low, a read reset is asserted via a logical high of the read reset signal RSTRD and the overall reset signal RSP going to logical low. This allows the reset signal RSP to reset the internal clock signal CKP (e.g., shut off) from the internal clock 106 which in turn resets the reference word line signal RWL. The internal clock signal CKP then pre-charges the tracking bit line signal TBL which in turn pulls the read reset signal RSTRD to logical low. With the read reset signal RSTRD pulled to logical low, the overall reset signal RSP is reset and ready for the next read or write operation.

During typical read operations, bit line capacitance is discharged via the series of pass gate and pull down N-channel MOSFET devices of the accessed memory cell in the memory cell array 103. In this tracking scheme, the tracking bit lines BT and BB are similarly discharged by the series combinations of the pass gate and pull down N-channel MOSFET devices in the read/write tracking cell 104 (i.e., N-channel MOSFET devices 406, 407, 408, and 409), thereby tracking the read operation.

FIG. 8 illustrates a signaling diagram during an exemplary write tracking operation. Again, an external clock is provided to the clock 106 to generate the internal clock signal CKP. The internal clock signal CKP along with the dummy predecoder line DPD generates the reference word line signal RWL. During a write cycle, the write enable signal WEA is asserted high. On the basis of previous data stored in the read/write tracking cell 104, either the write tracking bit line signal WRBT or its complement WRBB goes logical high. The states of the RGB and RBB nodes are also set based on the previous state of the read/write tracking cell 104. Thus, if the write tracking bit line signal WRBT goes to logical high, the bit line tracking signal BT is pulled to logical low and the bit line tracking signal BB remains logical high because the write tracking bit line signal to the WRBB remains logical low. This causes the internal node sensor of the MOSFETs 410 and 413 to pull the RBB node to logical low. The RTB node is already logical low because the previous state of the read/write tracking cell 104. Thus, with the RBB node going to logical low, the write reset signal RSTWR is pulled to logical high which in turn pulls the overall reset signal RSP logical low, thereby resetting the internal clock 106. From there, internal clock signal CKP resets the reference word line RWL and pre-charges the tracking bit lines BT and BB. With the tracking bit lines BT and BB precharged, the tracking bit lines BB and BT then pull the internal node RBB of the read/write tracking cell 104 to logical high which resets the write reset signal RSTWR. The write reset signal RSTWR in turn resets the overall reset signal RSP such that a subsequent read or write operation can be properly tracked.

During a typical write operation, a bit line driver drives one of the bit lines to the memory cell array 103 to a logical low. If a corresponding side of the memory cell being accessed is storing a logical high bit, then with the arrival of the word lines, the content of the memory cell is “flipped” causing the stored logical high to go to logical low. In this tracking scheme, the write tracking operation is done in a similar fashion with the write driver pulling down one of the tracking bit lines BB or BT to a logical low. A logical low of the tracking bit line BT/BB is coupled through the pass gate to the internal node storing the logical high state in the memory cell of the read/write tracking cell 104 (i.e., the MOSFETs 404, 405, 407, and 408). Thus, with the arrival of the reference word line signal RWL, the read/write tracking cell 104 is flipped from logical high to logical low, thereby completing the tracking of the write operation.

The invention can take the form of an entirely hardware embodiment, an entirely software embodiment or an embodiment containing both hardware and software elements. In one embodiment, the invention is implemented in software, which includes but is not limited to firmware, resident software, microcode, etc. FIG. 7 illustrates a computing system 700 in which a computer readable medium 706 may provide instructions for performing any of the methods disclosed herein.

Furthermore, the invention can take the form of a computer program product accessible from the computer readable medium 706 providing program code for use by or in connection with a computer or any instruction execution system. For the purposes of this description, the computer readable medium 706 can be any apparatus that can tangibly store the program for use by or in connection with the instruction execution system, apparatus, or device, including the computer system 700.

The medium 706 can be any tangible electronic, magnetic, optical, electromagnetic, infrared, or semiconductor system (or apparatus or device). Examples of a computer readable medium 706 include a semiconductor or solid state memory, magnetic tape, a removable computer diskette, a random access memory (RAM), a read-only memory (ROM), a rigid magnetic disk and an optical disk. Some examples of optical disks include compact disk-read only memory (CD-ROM), compact disk - read/write (CD-R/W) and DVD.

The computing system 700, suitable for storing and/or executing program code, can include one or more processors 702 coupled directly or indirectly to memory 708 through a system bus 710. The memory 708 can include local memory employed during actual execution of the program code, bulk storage, and cache memories which provide temporary storage of at least some program code in order to reduce the number of times code is retrieved from bulk storage during execution. Input/output or I/O devices 704 (including but not limited to keyboards, displays, pointing devices, etc.) can be coupled to the system either directly or through intervening I/O controllers. Network adapters may also be coupled to the system to enable the computing system 700 to become coupled to other data processing systems, such as through host systems interfaces 712, or remote printers or storage devices through intervening private or public networks. Modems, cable modem and Ethernet cards are just a few of the currently available types of network adapters.

What is claimed is:

1. A Static Random Access Memory device, comprising:
a clock;
a memory cell array;
a column of dummy bit cells operable to mirror bit line loading of the memory cell array; and
a row of dummy bit cells operable to mirror word line loading of the memory cell array; and
a read/write tracking cell operable to track read operations from the memory cell array via the dummy bit cells, to track write operations to the memory cell array via the dummy bit cells, and to reset the clock based on the tracked read operations and the tracked write operations

2. The device of claim 1, wherein:
the read/write tracking cell is further operable to reset the clock based on one of the write operations to track another read operation to the memory cell array after the clock is reset.

3. The device of claim 1, wherein:
the read/write tracking cell is further operable to discharge bit line capacitance to track another read operation.

4. The device of claim 3, wherein:
the read/write tracking cell comprises three P-channel Metal Oxide Semiconductor Field Effect Transistors each having gates coupled to receive a clock signal from the clock to discharge the bit line capacitance.

5. The device of claim 1, wherein:
the read/write tracking cell is further operable to pre-charge bit line capacitance of the device before another write operation.

6. The device of claim 5, wherein:
the read/write tracking cell comprises three P-channel Metal Oxide Semiconductor Field Effect Transistors each having gates coupled to receive a clock signal from the clock to pre-charge the bit lines of the device.

7. The device of claim 1, wherein:
the device is a single-port Synchronous Random Access Memory device.

8. A method operable in a Static Random Access Memory device, the method comprising:
mirroring word line loading and bit line loading to a memory cell array in the device;
tracking a write operation to the memory cell array via a read/write tracking cell;
resetting a clock of the device via the read/write tracking cell;
tracking a read operation from the memory cell array via the read/write tracking cell; and
resetting the clock of the device via the read/write tracking cell for either a subsequent read operation to the memory cell array or a subsequent write operation to the memory cell array.

9. The method of claim 8, further comprising:
tracking another read operation from the memory cell array after the clock is reset.

10. The method of claim 8, further comprising:
tracking another write operation to the memory cell array after the clock is reset.

11. The method of claim 8, further comprising:
discharging bit line capacitance to track the read operation via the read/write tracking cell.

12. The method of claim 11, further comprising:
receiving a clock signal from the clock at gates of three P-channel Metal Oxide Semiconductor Field Effect Transistors of the read/write tracking cell to discharge the bit line capacitance.

13. The method of claim 8, further comprising:
pre-charging bit line capacitance of the device via the read/write tracking cell before the write operation.

14. The method of claim 13, further comprising:
receiving a clock signal from the clock at gates of three P-channel Metal Oxide Semiconductor Field Effect Transistors of the read/write tracking cell to pre-charge the bit line capacitance.
